(19) United States
(12) Patent Application Publication
(10) Pub. No.: US 2022/0416651 A1
(43) Pub. Date: Dec. 29, 2022

(54) POWER CONVERSION DEVICE AND POWER CONVERSION SYSTEM

(71) Applicants: FLOSFIA INC., Kyoto (JP); MITSUBISHI HEAVY INDUSTRIES, LTD., Tokyo (JP)

(72) Inventors: Masato ITO, Tokyo (JP); Masaya MITAKE, Tokyo (JP); Yukio YAMASHITA, Tokyo (JP); Shogo MIZUMOTO, Kyoto (JP); Hideaki YANAGIDA, Kyoto (JP); Takashi SHINOHE, Kyoto (JP)

(21) Appl. No.: 17/895,598

(22) Filed: Aug. 25, 2022

Related U.S. Application Data
(63) Continuation-in-part of application No. PCT/JP2021/003270, filed on Jan. 29, 2021.

(30) Foreign Application Priority Data
Feb. 25, 2020 (JP) 2020-029479

(51) Int. Cl. H02M 1/36; H02M 1/00; H05K 1/02; H05K 1/18; H02M 1/32

(52) U.S. Cl. CPC H02M 1/36; H02M 1/0009; H05K 1/0298; H05K 1/181; H02M 1/32; H05K 2201/1003; H05K 2201/09236

(57) ABSTRACT

Provided is a power conversion device converting power and supplying the converted power to a load, the power conversion device including: a power conversion circuit connected to the load and configured to supply/receive the power; a coil configured to detect a current passing through the power conversion circuit and to output a voltage corresponding to the detected current; an integration circuit configured to integrate the voltage output from the coil to generate a voltage signal corresponding to a variation of the current; and a control device configured to generate a control signal to the power conversion circuit based on the voltage signal output from the integration circuit.

### CROSS REFERENCE TO RELATED APPLICATION

This application is a continuation-in-part application of International Patent Application No. PCT/JP2021/003270 (Filed on Jan. 29, 2021), which claims the benefit of priority from Japanese Patent Application No. 2020-029479 (filed on Feb. 25, 2020).

The entire contents of the above applications, which the present application is based on, are incorporated herein by reference.

### 1. Field of the Invention

The present disclosure relates to a power conversion device and a power conversion system, and particularly to a power conversion device and a power conversion system each easily detecting an overcurrent without change of a basic configuration of a power conversion circuit.

### 2. Description of the Related Art

As a power conversion device that converts power and supplies the converted power to a load, for example, an inverter that converts a direct current into an alternating current to drive a load, a converter that converts an alternating current into a direct current, and a diode that receives a super high-voltage current and downsizes the current to a desired current value are known. Each of these power conversion devices controls a power conversion circuit in which an input terminal is connected to a storage battery or an external power supply, and an output terminal is connected to a load, thereby performing appropriate drive control of the load.

Such a power conversion device includes a shutdown function that detects an overcurrent when the overcurrent occurs due to any factor, and immediately stops operation of the power conversion circuit (more specifically, switching operation by switching element). For example, in a case where a comparator circuit determines a magnitude of a voltage generated between terminals of a current detection shunt resistor, and the detected voltage exceeds a predetermined determination threshold, a signal is input to a shutdown signal input terminal of a gate driver, a control signal to stop operation of the power conversion circuit is generated, and operation of the load is accordingly stopped.

Further, as a technique relating thereto, an overcurrent detection device that more surely detects an overcurrent caused by an overload state or a short circuit state by grasping a current and a variation of the current from an inter-terminal voltage of a resistor and an inter-terminal voltage of a coil, has been disclosed.

### SUMMARY OF THE INVENTION

According to an example of the present disclosure, there is provided a power conversion device converting power and supplying the converted power to a load, the power conversion device including: a power conversion circuit connected to the load and configured to supply/receive the power; a coil configured to detect a current passing through the power conversion circuit and to output a voltage corresponding to the detected current; an integration circuit configured to integrate the voltage output from the coil to generate a voltage signal corresponding to a variation of the current; and a control device configured to generate a control signal to the power conversion circuit based on the voltage signal output from the integration circuit.

According to an example of the present disclosure, there is provided a power conversion system, including: a power supply; a load configured to operate by power from the power supply; and a power conversion device configured to convert the power from the power supply and to supply the converted power to the load, the power conversion device including a power conversion circuit, a coil, an integration circuit, and a control device, the power conversion circuit being connected to the load and being configured to supply/receive the power, the coil being configured to detect a current passing through the power conversion circuit and to output a voltage corresponding to the detected current, the integration circuit being configured to integrate the voltage output from the coil to generate a voltage signal corresponding to a variation of the current, the control device being configured to generate a control signal to the power conversion circuit based on the voltage signal output from the integration circuit.

Thus, in a power conversion device of the present disclosure and a power conversion system of the present disclosure, it is possible to easily detect the overcurrent without change of the basic configuration of the power conversion circuit.

### BRIEF DESCRIPTION OF THE DRAWINGS

FIG. 1 is a diagram illustrating an entire configuration of a power conversion device according to an embodiment of the present disclosure.

FIG. 2 is a schematic diagram to explain a current detection mechanism by a coil according to the embodiment of the present disclosure.

FIG. 3 is a schematic diagram to explain a voltage signal obtained by the coil and an integration circuit according to the embodiment of the present disclosure.

FIG. 4 is a waveform diagram of the voltage signal detected by the coil according to the embodiment of the present disclosure.

### DETAILED DESCRIPTION

The inventors of the present disclosure found out that conventional overcurrent detection methods adopt a circuit configuration in which a measured value of the current flowing through the power conversion circuit is input/output to grasp a state of the overcurrent, and then signal processing is performed, it is necessary to reconstruct the circuit configuration of the power conversion circuit itself based on the load to be controlled. Further, when it is necessary to change a resistance constant and allowable power based on the control target, modularization and commonalization of the power conversion circuit become difficult. This acts as a barrier of generalization and popularization of the power conversion device, and is undesirable.

Embodiments of the present disclosure will be described below with reference to the accompanying drawings. In the following description, the same parts and components are designated by the same reference numerals. The present embodiment includes, for example, the following disclosures.

[Structure 1]

A power conversion device converting power and supplying the converted power to a load, the power conversion device including: a power conversion circuit connected to the load and configured to supply/receive the power; a coil configured to detect a current passing through the power conversion circuit and to output a voltage corresponding to the detected current; an integration circuit configured to integrate the voltage output from the coil to generate a voltage signal corresponding to a variation of the current; and a control device configured to generate a control signal to the power conversion circuit based on the voltage signal output from the integration circuit.

[Structure 2]

The power conversion device according to [Structure 1], wherein the coil includes a pattern coil provided on a substrate to surround a wiring line guiding the current passing through the power conversion circuit.

[Structure 3]

The power conversion device according to [Structure 2], wherein the coil is formed in a shape along an outer periphery of the wiring line near the wiring line.

[Structure 4]

The power conversion device according to [Structure 2], wherein the substrate is a multilayer wiring substrate, and the coil is continuously provided over a plurality of layers of the multilayer substrate.

[Structure 5]

The power conversion device according to [Structure 4], wherein a plurality of the wiring lines are arranged electrically in parallel over the plurality of layers of the multilayer wiring substrate.

[Structure 6]

The power conversion device according to [Structure 1], wherein the control device generates the control signal to resume or stop operation of the power conversion circuit based on the voltage signal input from the integration circuit.

[Structure 7]

The power conversion device according to [Structure 6], wherein the power conversion circuit includes a switching unit configured to turn ON/OFF the power supplied/received to/from the load, and the control device generates the control signal relating to ON/OFF of the switching unit.

[Structure 8]

A power conversion system, including: a power supply; a load configured to operate by power from the power supply; and a power conversion device configured to convert the power from the power supply and to supply the converted power to the load, the power conversion device including a power conversion circuit, a coil, an integration circuit, and a control device, the power conversion circuit being connected to the load and being configured to supply/receive the power, the coil being configured to detect a current passing through the power conversion circuit and to output a voltage corresponding to the detected current, the integration circuit being configured to integrate the voltage output from the coil to generate a voltage signal corresponding to a variation of the current, the control device being configured to generate a control signal to the power conversion circuit based on the voltage signal output from the integration circuit.

[Structure 9]

The power conversion system according to [Structure 8], wherein the coil includes a pattern coil provided on a substrate to surround a wiring line guiding the current passing through the power conversion circuit.

[Structure 10]

The power conversion system according to [Structure 9], wherein the coil is formed in a shape along an outer periphery of the wiring line near the wiring line.

[Structure 11]

The power conversion system according to [Structure 9], wherein the substrate is a multilayer wiring substrate, and the coil is continuously provided over a plurality of layers of the multilayer wiring substrate.

[Structure 12]

The power conversion system according to [Structure 11], wherein a plurality of the wiring lines are arranged electrically in parallel over the plurality of layers of the multilayer wiring substrate.

[Structure 13]

The power conversion system according to [Structure 8], wherein the control device generates the control signal to resume or stop operation of the power conversion circuit based on the voltage signal input from the integration circuit.

[Structure 14]

The power conversion system according to [Structure 13], wherein the power conversion circuit includes a switching unit configured to turn ON/OFF the power supplied/received to/from the load, and the control device generates the control signal relating to ON/OFF of the switching unit.

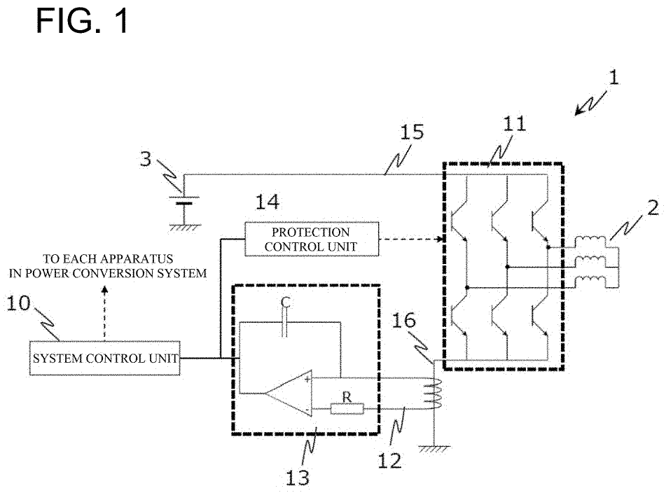

A power conversion device and a power conversion system according to an embodiment of the present disclosure are described below with reference to FIG. 1 to FIG. 4.

FIG. 1 is a circuit diagram illustrating an entire configuration of a power conversion device according to a first embodiment.

The power conversion device 1 illustrated in FIG. 1 is an inverter that converts a direct-current power supplied from power supply 3 into three-phase alternating-current power, thereby driving a load 2. The load 2 is an alternating-current motor, and is an electric motor driven by the three-phase alternating-current power supplied from the power conversion device 1. The electric motor 2 is mounted on, for example, an electric vehicle and a hybrid car, and generates driving force for an electric apparatus. In this case, examples of the power supply 3 include an on-vehicle storage battery.

The power conversion device 1 further includes a system control unit 10, a power conversion circuit 11, a coil 12, an integration circuit 13, and a protection control unit (control device) 14. In the present embodiment, the coil 12 and the integration circuit 13 configure an overcurrent detection device.

Note that the power conversion device 1, the power supply 3, and the load 2 configure the power conversion system.

The system control unit 10 controls operation of the whole of the power conversion system including the power conversion device 1. The system control unit 10 functions as a gate driver that outputs a driving signal to the power conversion circuit 11 to control driving of the power conversion circuit 11, and generates a control signal to a monitoring device, a backup apparatus, and the like not illustrated. The system control unit 10 is realized by, for example, a microcomputer mounted with a CPU (Central Processing Unit). The system control unit 10 is disposed in, for example, a central control room.

The power conversion circuit 11 converts the direct-current power supplied from the storage battery 3 into the three-phase alternating-current power by being driven based on the control signal from the system control unit 10. The power conversion circuit 11 includes six switching elements SW. Each of the switching elements SW is switched to an ON state where a, current is allowed to flow or an OFF state where the current is shut off, based on the driving signal (gate input) from the system control unit 10. Two switching elements SW are connected in series between a high-potential line 15 (wiring line to which high-potential side of storage battery 3 is connected) and a low-potential line 16 (wiring line passing, through coil 12 and grounded), corresponding to each of a U-phase, a V-phase, and a W-phase configuring the three-phase alternating current. When each of the switching elements SW repeats ON/OFF at prescribed timings, the three-phase (U-phase, V-phase, and W-phase) alternating-current power is supplied to the alternating-current motor 2.

As each of the switching elements SW provided in the power conversion circuit 11, for example, an IGBT (Insulated Gate Bipolar Transistor) is representative; however, a bipolar transistor, an MOSFET (Metal-Oxide-Semiconductor Field effect transistor), or the like may be used.

The coil 12 is disposed between the power conversion circuit 11 and a ground point so as to have positional relationship in which a part of the low-potential line 16 is inserted into and surrounded by the coil 12.

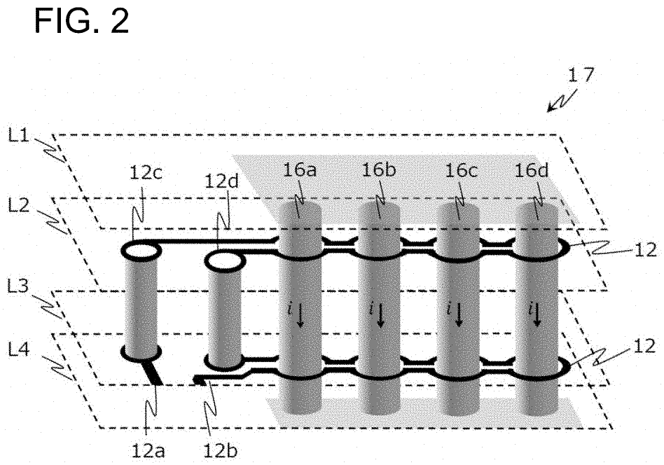

FIG. 2 is a schematic diagram to explain a current detection mechanism by the coil 12 according to the present embodiment, and illustrates positional relationship between the low-potential line 16 and the coil 12. As illustrated in the drawing, a circuit substrate 17 mounted with the power conversion circuit 11 is configured as a multilayer substrate, and includes an aggregate of a plurality of layers L1 to L4. A plurality of branched low-potential lines 16a to 16d are arranged in parallel so as to penetrate through the layers L1 to L4.

The coil 12 according to the present embodiment has one end 12a and the other end 12b formed on the layer L3, and is configured so as to detect a current I in each of the layer L2 and the layer L3 to the low-potential lines 16a to 16d. More specifically, the coil 12 is laid so as to reciprocate between the low-potential lines 16a to 16d in each of the layers L2 and L3, and is formed in a shape bent in an annular shape so as to surround the low-potential lines 16a to 16d along peripheries near the low-potential lines 16a, to 16d. Further, conductive portions 12c and 12d each made of a conductive member electrically connect the coil 12 between the layers L2 and L3. Accordingly, the coil 12 is made of one coil line from the one end 12a to the other end 12b laid over the layers. Note that the low-potential lines 16a to 16d are configured by one low-potential line 16 outside the layers L1 and L4. The one low-potential line 16 is parallelly branched over the layers L1 to L4. As a result, a current i flows through each of the low-potential lines 16a to 16d.

The above-described coil 12 according to the present embodiment is a so-called pattern coil fanned by previously printing a wiring line on predetermined layers of the circuit substrate 17, and serves as a high-frequency pattern inductor. Appropriately changing routing, a shape, and the like of the wiring line near the low-potential lines 16a to 16d and other portions makes it possible to realize optional coil characteristics.

By using the coil 12 fabricated in the above-described manner, the current flowing through the low-potential line 16 (16a to 16e) is detected, and a voltage signal corresponding to a detected value is output from the coil 12.

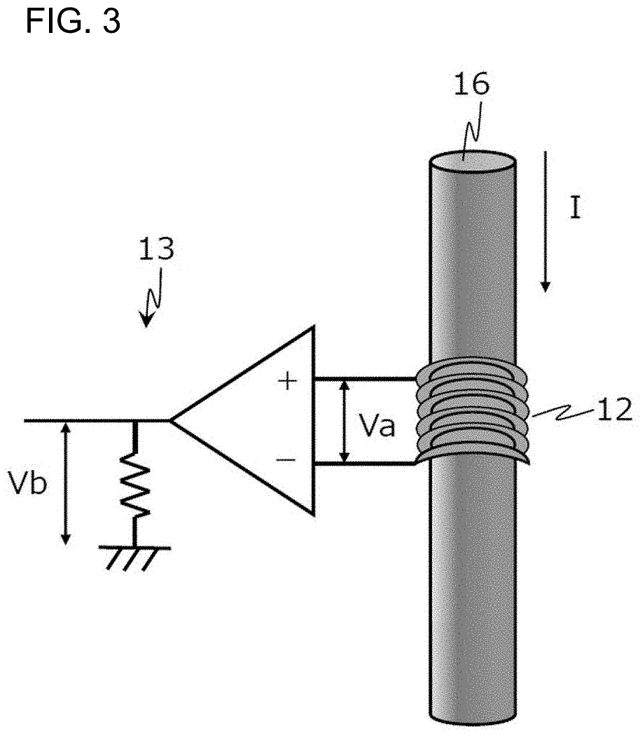

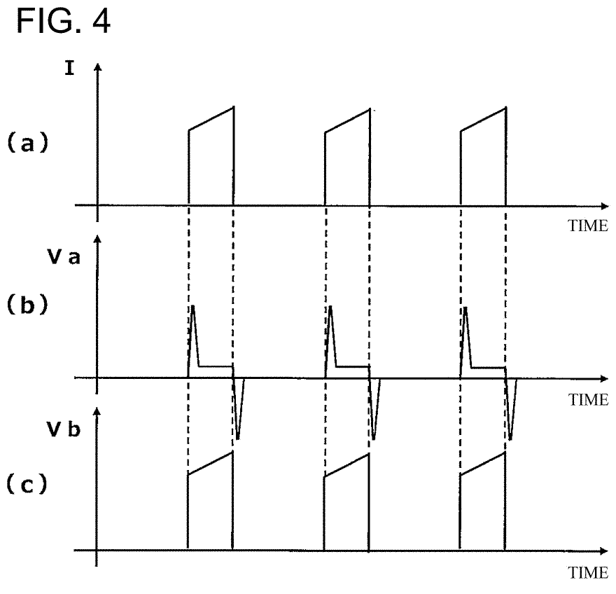

The voltage signal detected by the coil 12 corresponds to a time change rate of the current flowing through the low-potential line 16 (16a to 16e). Therefore, to obtain a value corresponding to an actual current I, it is necessary to perform time integration of the voltage signal. Therefore, the integration circuit 13 receives the output signal from the coil 12 and performs time integration, which results in a linear time waveform reflecting change of the current I. Detailed descriptions are given below with reference to FIG. 3 and FIG. 4.

FIG. 3 is a schematic diagram to e plain the voltage signal obtained by the coil 12 and the integration circuit 13, and FIG. 4 is a waveform diagram of the voltage signal detected in FIG. 3. First, the current I flowing through the low-potential line 16 is represented as a pulse signal corresponding to switching operation of the power conversion circuit 11, as illustrated in FIG. 4A. On the other hand, the coil 12 disposed around the low-potential line 16 detects a voltage difference between both ends of the coil 12. The detection corresponds to detection of a time change rate di/dt of the current I. Therefore, a voltage signal Va having a waveform as illustrated in, for example, FIG. 4B is detected. Thereafter, the integration circuit 13 receives the detected voltage signal Va and performs the time integration. As a result, a voltage signal Vb (FIG. 4C) reflecting the time waveform of the current I (FIG. 4A) is obtained. Accordingly, combining the coil 12 and the integration circuit 13 makes it possible to detect and reproduce the voltage signal corresponding to the variation of the current I flowing through the low-potential line 16.

The detected voltage signal Vb is input to the protection control unit 14 in the power conversion device 1 illustrated in FIG. 1. The protection control unit 14 internally includes a reference table. In a case where the current I having passed through the coil 12 is an overcurrent based on the input voltage signal Vb, the protection control unit 14 determines a factor of the overcurrent through comparison with the reference table. As a reference to determine the factor of the overcurrent, a determination reference based on change in the current value with time may be set with reference to a design specification of the power conversion circuit 11, a design specification of the load 2, and the like.

As the factor in the case where the current I is the overcurrent, a case where the high-potential line 15 and the low-potential line 16 in the power conversion circuit 11 are short-circuited through the switching elements (switching short circuit), and a case where the high-potential line 15 and the low-potential line 16 are short-circuited through the load 2. (load short circuit) are considered. In the case of the switching short circuit, failure of ON/OFF switching of any of the switching elements is considered. Therefore, it is necessary to stop energization to the power conversion circuit 11. In contrast, in the case of the load short circuit, mechanical failure of the load 2, noise overlapping with the driving signal supplied to the load 2, or the like is considered. Therefore, recovery may be possible by resetting the control of the power conversion circuit 11 and performing reenergization. It is possible to determine the factor of the short circuit from change in the voltage signal Vb with time, namely, an elapsed time until the voltage signal Vb changes from a normal value to a value corresponding to the overcurrent. The protection control unit 14 detects the switching short circuit or the load short circuit in real time by successively comparing the change in the voltage signal Vb with time, with the reference table, and determines whether to resume energization to the power conversion circuit 11. Further, the protection control unit 14 controls operation of the switching elements by feeding back an appropriate control signal to the power conversion circuit 11.

For example, in a case where the switching short circuit is detected, the OFF state of each of the switching elements is maintained to establish an operation stop state. In a case where the load short circuit is detected, the switching elements are turned off once, and then ON/OFF operation is started to resume operation.

The voltage signal Vb output from the integration circuit 13 is input to the system control unit 10 in parallel with the protection control unit 14. In a case where it is determined that the current I is the overcurrent, the system control unit 10 generates an alarm signal in the central control room, or generates a control signal to an apparatus belonging to the power conversion system including the power conversion device 1 according to the present disclosure. More specifically, the system control unit 10 generates a control signal to perform deceleration operation or stop operation based on detection of the overcurrent, for an optional apparatus (control target) in the system, or generates a startup signal for a backup apparatus based on emergency stop of the power conversion device 1, and outputs the control signal to the control target. These control signals may be generated based on a determination result by an operator in the central control room or the like.

In the power conversion device 1 and the power conversion system configured as described above according to the embodiment of the present disclosure, not the current I itself of the power conversion circuit 11 but the voltage signal from the coil 12 detecting the current I is used for the signal processing of the overcurrent detection. Therefore, since the circuit for the overcurrent detection is configured while being insulated from the power conversion circuit 11, flexibility in circuit design is significantly improved. In other words, it is possible to easily detect the overcurrent without change of the basic configuration of the power conversion circuit.

Along therewith, the power conversion circuit 11 as hardware is generally usable irrespective of a type of the load. This makes it possible to enhance stability as the power conversion device. For example, in a case where the power conversion circuit 11 is modularized and commonalized, it is possible to easily adjust a threshold of the overcurrent by using the other external resistor without changing the configuration of the coil 12 based on the load 2.

Further, in the power conversion device 1 and the power conversion system according to the embodiment of the present disclosure, the coil 12 is fabricated by a so-called pattern coil printed on the substrate. Therefore, as compared with a case where the coil 12 is fabricated by a winding coil, it is possible to reduce manufacturing processes and a manufacturing cost. In particular, when a space for creation of the coil is suitably secured on the substrate, the overcurrent is detectable only by reproducing the coil 12 having desired characteristics on the substrate without change of the circuit configuration of the power conversion circuit 11.

The coil is not limited to the pattern coil printed on the substrate as a matter of course, the other well-known coil is usable. Even in this case, it is possible to easily adjust the threshold of the overcurrent by using the other external resistor without changing the configuration of the coil based on the load.

The present disclosure is not limited to the above-described embodiment, and is variously modified and implemented without departing from the spirit of the present disclosure.

In the above-described embodiment, the case where the power conversion circuit 11 of the power conversion device 1 converts direct-current power into alternating-current power, and supplies the converted power to the load is exemplified; however, the effects by the present disclosure are expected in the other cases. More specifically, to apply the power conversion device 1 to a high-speed railway vehicle such as a bullet train, the power conversion device 1 is mountable as a converter, and is used to generate, for example, driving force for an electric apparatus inside the vehicle. In this case, the power supply 3 is an alternating-current power supply connected through an overhead line, and the power is sequentially supplied through a converter and an inverter to drive the alternating-current motor as the load 2. The effects by the present disclosure are also expected when an application target includes only the converter, as a matter of course. Further, the present disclosure is applicable to the power conversion device 1 to step down large power. Accordingly, the power conversion device 1 according to the present disclosure is not applied only to power conversion from the direct-current power to the alternating-current power.

Further, when a material having low on-resistance, such as silicon oxide (SiC) and gallium nitride (GaN) is used for each of the switching elements in the power conversion circuit 11 of the power conversion device 1 according to the present disclosure, it is possible to improve the switching characteristics. Further, gallium oxide (Ga₂O₃), in particular, corundum-type gallium oxide (α-Ga₂O₃) is preferably used as the material of each of the switching elements. In this case, extremely excellent switching characteristics are expected, and downsizing and cost reduction of the power conversion device 1 are realized.

The embodiments of the present invention are exemplified in all respects, and the scope of the present invention includes all modifications within the meaning and scope equivalent to the scope of claims.

### Reference Signs List

1 Power conversion device
2 Load
3 Power supply
10 System control unit
11 Power conversion circuit
12 Coil
13 Integration circuit
14 Protection control unit (control device)
15 High-potential line
16 Low-potential line
17 Circuit substrate

What is claimed is:

1. A power conversion device converting power and supplying the converted power to a load, the power conversion device comprising:
a power conversion circuit connected to the load and configured to supply/receive the power;
a coil configured to detect a current passing through the power conversion circuit and to output a voltage corresponding to the detected current;
an integration circuit configured to integrate the voltage output from the coil to generate a voltage signal corresponding to a variation of the current; and
a control device configured to generate a control signal to the power conversion circuit based on the voltage signal output from the integration circuit.

2. The power conversion device according to claim 1, wherein the coil includes a pattern coil provided on a substrate to surround a wiring line guiding the current passing through the power conversion circuit.

3. The power conversion device according to claim 2, wherein the coil is formed in a shape along an outer periphery of the wiring line near the wiring line.

4. The power conversion device according to claim 2, wherein
the substrate is a multilayer wiring substrate, and
the coil is continuously provided over a plurality of layers of the multilayer wiring substrate.

5. The power conversion device according to claim 4, wherein a plurality of the wiring lines are arranged electrically in parallel over the plurality of layers of the multilayer wiring substrate.

6. The power conversion device according to claim 1, wherein the control device generates the control signal to resume or stop operation of the power conversion circuit based on the voltage signal input from the integration circuit.

7. The power conversion device according to claim 6, wherein
the power conversion circuit includes a switching unit configured to turn ON/OFF the power supplied/received to/from the load, and
the control device generates the control signal relating to ON/OFF of the switching unit.

8. A power conversion system, comprising:
a power supply;
a load configured to operate by power from the power supply; and
a power conversion device configured to convert the power from the power supply and to supply the converted power to the load,
the power conversion device including a power conversion circuit, a coil, an integration circuit, and a control device , the power conversion circuit being connected to the load and being configured to supply/receive the power, the coil being configured to detect a current passing through the power conversion circuit and to output a voltage corresponding to the detected current, the integration circuit being configured to integrate the voltage output from the coil to generate a voltage signal corresponding to a variation of the current, the control device being configured to generate a control signal to the power conversion circuit based on the voltage signal output from the integration circuit.

9. The power conversion system according to claim 8, wherein the coil includes a pattern coil provided on a substrate to surround a wiring line guiding the current passing through the power conversion circuit.

10. The power conversion system according to claim 9, wherein the coil is formed in a shape along an outer periphery of the wiring line near the wiring line.

11. The power conversion system according to claim 9, wherein
the substrate is a multilayer wiring substrate, and
the coil is continuously provided over a plurality of layers of the multilayer wiring substrate.

12. The power conversion system according to claim 11, wherein a plurality of the wiring lines are arranged electrically in parallel over the plurality of layers of the multilayer wiring substrate.

13. The power conversion system according to claim 8, wherein the control device generates the control signal to resume or stop operation of the power conversion circuit based on the voltage signal input from the integration circuit.

14. The power conversion system according to claim 13, wherein
the power conversion circuit includes a switching unit configured to turn ON/OFF the power supplied/received to/from the load, and
the control device generates the control signal relating to ON/OFF of the switching unit.
